(19) United States
(12) Patent Application Publication
(10) Pub. No.: US 2014/0218706 A1
(43) Pub. Date: Aug. 7, 2014

(54) RADIATION SOURCE AND LITHOGRAPHIC APPARATUS

(71) Applicants: Christian Wagner, Duizel (DE); Erik Roelof Loopstra, Eindhoven (NL)

(72) Inventors: Christian Wagner, Duizel (DE); Erik Roelof Loopstra, Eindhoven (NL)

(73) Assignee: ASML Netherlands B.V., Veldhoven (NL)

(21) Appl. No.: 14/241,370

(22) PCT Filed: Jul. 27, 2012
(86) PCT No.: PCT/EP2012/064789

§ 371 Date: Feb. 26, 2014

Related U.S. Application Data
(60) Provisional application No. 61/530,741, filed on Sep. 2, 2011.

(51) Int. Cl. G03F 7/20; H05G 2/00

(52) U.S. Cl. CPC G03F 7/70058; H05G 2/008; H05G 2/006
USPC 355/67; 250/504 R

(57) ABSTRACT

A radiation source comprises a nozzle configured to direct a stream of fuel droplets (400) along a trajectory towards a plasma formation location and a laser configured to direct laser radiation to the plasma formation location to convert the fuel droplets at the plasma formation location into a plasma. The laser comprises an amplifier (310, 320) and an optical element (500) configured to define a divergent beam path for radiation passing through the amplifier.

### CROSS-REFERENCE TO RELATED APPLICATIONS

This application claims the benefit of U.S. provisional application 61/530,741, which was filed on Sep. 2, 2012, and which is incorporated herein in its entirety by reference.

### FIELD

The present invention relates to a radiation source and to a lithographic apparatus.

### BACKGROUND

A lithographic apparatus is a machine that applies a desired pattern onto a substrate, usually onto a target portion of the substrate. A lithographic apparatus can be used, for example, in the manufacture of integrated circuits (ICs). In that instance, a patterning device, which is alternatively referred to as a mask or a reticle, may be used to generate a circuit pattern to be formed on an individual layer of the IC. This pattern can be transferred onto a target portion (e.g., comprising part of, one, or several dies) on a substrate (e.g., a silicon wafer). Transfer of the pattern is typically via imaging onto a layer of radiation-sensitive material (resist) provided on the substrate. In general, a single substrate will contain a network of adjacent target portions that are successively patterned.

Lithography is widely recognized as one of the key steps in the manufacture of ICs and other devices and/or structures. However, as the dimensions of features made using lithography become smaller, lithography is becoming a more critical factor for enabling miniature IC or other devices and/or structures to be manufactured.

A theoretical estimate of the limits of pattern printing can be given by the Rayleigh criterion for resolution as shown in equation (1):

$$CD = {k}_{1} * \frac{λ}{NA} \qquad ( 1 )$$

where λ is the wavelength of the radiation used, NA is the numerical aperture of the projection system used to print the pattern, k₁ is a process dependent adjustment factor, also called the Rayleigh constant, and CD is the feature size (or critical dimension) of the printed feature. It follows from equation (1) that reduction of the minimum printable size of features can be obtained in three ways: by shortening the exposure wavelength λ, by increasing the numerical aperture NA or by decreasing the value of k₁.

In order to shorten the exposure wavelength and, thus reduce the minimum printable size, it has been proposed to use an extreme ultraviolet (EUV) radiation source. EUV radiation is electromagnetic radiation having a wavelength within the range of 5-20 nm, for example within the range of 13-14 nm, for example within the range of 5-10 nm such as 6.7 nm or 6.8 nm. Possible sources include, for example, laser-produced plasma sources, discharge plasma sources, or sources based on synchrotron radiation provided by an electron storage ring.

EUV radiation may be produced using a plasma. A radiation system for producing EUV radiation may include a laser for exciting a fuel to provide the plasma, and a source collector module for containing the plasma. The plasma may be created, for example, by directing a laser beam at a fuel, such as droplets of a suitable material (e.g., tin), or a stream of a suitable gas or vapor, such as Xe gas or Li vapor. The resulting plasma emits output radiation, e.g., EUV radiation, which is collected using a radiation collector. The radiation collector may be a mirrored normal incidence radiation collector, which receives the radiation and focuses the radiation into a beam. The source collector module may include an enclosing structure or chamber arranged to provide a vacuum environment to support the plasma. Such a radiation system is typically termed a laser produced plasma (LPP) source.

It can be difficult to consistently and accurately hit a series of moving droplets with a pulsed laser beam. For example, some high-volume EUV radiation sources may require the irradiation of droplets having a diameter of about 20-50 μm and moving at a velocity of about 50-100 m/s.

With the above in mind, systems and methods have been proposed for effectively delivering and focusing a laser beam to a selected location in an EUV radiation source.

U.S. Pat. No. 7,491,954 describes an EUV radiation source which comprises an optical gain medium and a lens which is arranged to direct radiation generated by the optical gain medium onto a droplet of fuel material. The optical gain medium and lens are arranged such that the optical gain medium generates laser radiation when the droplet of fuel material is at a predetermined location, thereby causing the droplet of fuel material to produce an EUV radiation emitting plasma. Since optical gain medium is triggered by the presence of the droplet of fuel material at the predetermined location, a seed laser is not required to trigger operation of the optical gain medium.

A problem associated with the type of system described in U.S. Pat. No. 7,491,954 is that because the lasing process starts by photons being reflected by droplets of fuel material such that the rays are reflected into themselves, the mode that builds-up is strongly dependent upon and confined around the initial trigger process. This in turn induces the following problems: the cavity is only used locally with the result that saturation effects in the gain medium limit the absolute power obtainable; and the moving droplet of fuel material flies by the initial trigger point, to which the laser fires back, with the result that the next reflection is less than optimal, which can lead to the development of an undesirable asymmetric mode.

### SUMMARY

It is desirable to provide a radiation source and lithographic apparatus which is novel and inventive compared with known radiation sources.

According to a first aspect of the present invention there is provided a radiation source comprising a nozzle configured to direct a stream of fuel droplets along a trajectory towards a plasma formation location and a laser configured to direct laser radiation to the plasma formation location to convert the fuel droplets at the plasma formation location into a plasma, wherein the laser comprises an amplifier and an optical element configured to define a divergent beam path for radiation passing through the amplifier.

The laser may be configured to generate a pulse of laser radiation when photons emitted from the amplifier are reflected along the divergent beam path by a fuel droplet. The laser may comprise a cavity mirror arranged to reflect photons reflected by fuel droplets, and the optical element may be provided in between the amplifier and the cavity mirror.

The amplifier may comprise a plurality of amplifier chambers. The optical element may be provided in between the cavity mirror and the amplifier chamber closest to the cavity minor.

In a first embodiment the optical element comprises a phase grating.

In a second embodiment the optical element comprises a scatter plate.

The radiation source may further comprise a collector mirror configured to collect and focus radiation generated by the plasma formed from the fuel droplets.

The plasma produced by conversion of the fuel droplets is preferably EUV radiation emitting plasma.

The laser radiation may have a wavelength of between about 9 μm and about 11 μm.

The nozzle may be configured to emit fuel droplets as single droplets. Alternatively, the nozzle may be configured to emit fuel droplets as clouds of fuel which subsequently coalesce into droplets.

The fuel droplets may comprise or consist of Xe, Li or Sn.

The laser is preferably a CO₂ laser.

According to a second aspect of the present invention there is provided a lithographic apparatus comprising the radiation source of the preceding aspect of the present invention, and further comprising an illumination system configured to condition a radiation beam, a support constructed to support a patterning device, the patterning device being capable of imparting the radiation beam with a pattern in its cross-section to form a patterned radiation beam, a substrate table constructed to hold a substrate, and a projection system configured to project the patterned radiation beam onto a target portion of the substrate.

According to a third aspect of the present invention there is provided a method comprising emitting a stream of fuel droplets from a nozzle along a trajectory towards a plasma formation location and using a laser to direct laser radiation to the plasma formation location to convert the fuel droplets at the plasma formation location into a plasma, wherein the laser comprises an amplifier and an optical element and the method further comprises using the optical element to define a divergent beam path for radiation passing through the amplifier.

Further features and advantages of the present invention, as well as the structure and operation of various embodiments of the present invention, are described in detail below with reference to the accompanying drawings. It is noted that the present invention is not limited to the specific embodiments described herein. Such embodiments are presented herein for illustrative purposes only. Additional embodiments will be apparent to persons skilled in the relevant art(s) based on the teachings contained herein.

### BRIEF DESCRIPTION OF THE DRAWINGS/FIGURES

The accompanying drawings, which are incorporated herein and form part of the specification, illustrate the present invention and, together with the description, further serve to explain the principles of the present invention and to enable a person skilled in the relevant art(s) to make and use the present invention.

FIG. 1 schematically depicts a lithographic apparatus according to an aspect of the present invention.

FIG. 2 is a more detailed view of the apparatus of FIG. 1, including an LPP source collector module.

FIG. 3 schematically depicts a radiation source according to the prior art.

FIG. 4 schematically depicts steps in the operation of the radiation source of FIG. 3.

FIG. 5 schematically depicts a radiation source according to a first embodiment of an aspect of the present invention, and

FIG. 6 schematically depicts a radiation source according to a second embodiment of an aspect of the present invention.

The features and advantages of the present invention will become more apparent from the detailed description set forth below when taken in conjunction with the drawings, in which like reference characters identify corresponding elements throughout. In the drawings, like reference numbers generally indicate identical, functionally similar, and/or structurally similar elements. The drawing in which an element first appears is indicated by the leftmost digit(s) in the corresponding reference number.

### DETAILED DESCRIPTION

This specification discloses one or more embodiments that incorporate the features of this invention. The disclosed embodiment(s) merely exemplify the present invention. The scope of the present invention is not limited to the disclosed embodiment(s). The present invention is defined by the claims appended hereto.

The embodiment(s) described, and references in the specification to “one embodiment”, “an embodiment”, “an example embodiment”, etc., indicate that the embodiment(s) described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is understood that it is within the knowledge of one skilled in the art to effect such feature, structure, or characteristic in connection with other embodiments whether or not explicitly described.

Embodiments of the present invention may be implemented in hardware, firmware, software, or any combination thereof. Embodiments of the present invention may also be implemented as instructions stored on a machine-readable medium, which may be read and executed by one or more processors. A machine-readable medium may include any mechanism for storing or transmitting information in a form readable by a machine (e.g., a computing device). For example, a machine-readable medium may include read only memory (ROM); random access memory (RAM); magnetic disk storage media; optical storage media; flash memory devices; electrical, optical, acoustical or other forms of propagated signals (e.g., carrier waves, infrared signals, digital signals, etc.), and others. Further, firmware, software, routines, instructions may be described herein as performing certain actions. However, it should be appreciated that such descriptions are merely for convenience and that such actions in fact result from computing devices, processors, controllers, or other devices executing the firmware, software, routines, instructions, etc.

Before describing such embodiments in more detail, however, it is instructive to present an example environment in which embodiments of the present invention may be implemented.

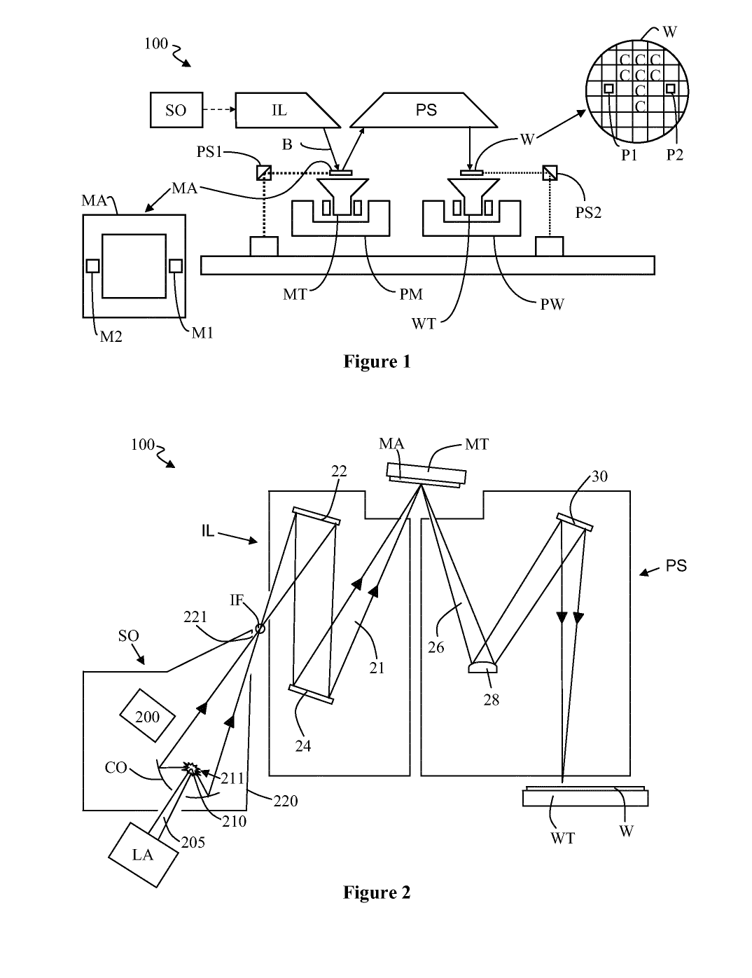

FIG. 1 schematically depicts a lithographic apparatus 100 according to an embodiment of the present invention. The lithographic apparatus includes an EUV radiation source according to an embodiment of the present invention. The apparatus comprises an illumination system (illuminator) IL configured to condition a radiation beam B (e.g., EUV radiation), a support structure (e.g., a mask table) MT constructed to support a patterning device (e.g., a mask or a reticle) MA and connected to a first positioner PM configured to accurately position the patterning device, a substrate table (e.g., a wafer table) WT constructed to hold a substrate (e.g., a resist-coated wafer) W and connected to a second positioner PW configured to accurately position the substrate; and a projection system (e.g., a reflective projection system) PS configured to project a pattern imparted to the radiation beam B by patterning device MA onto a target portion C (e.g., comprising one or more dies) of the substrate W.

The illumination system may include various types of optical components, such as refractive, reflective, magnetic, electromagnetic, electrostatic or other types of optical components, or any combination thereof, for directing, shaping, or controlling radiation.

The support structure MT holds the patterning device MA in a manner that depends on the orientation of the patterning device, the design of the lithographic apparatus, and other conditions, such as for example whether or not the patterning device is held in a vacuum environment. The support structure can use mechanical, vacuum, electrostatic or other clamping techniques to hold the patterning device. The support structure may be a frame or a table, for example, which may be fixed or movable as required. The support structure may ensure that the patterning device is at a desired position, for example with respect to the projection system.

The term “patterning device” should be broadly interpreted as referring to any device that can be used to impart a radiation beam with a pattern in its cross-section such as to create a pattern in a target portion of the substrate. The pattern imparted to the radiation beam may correspond to a particular functional layer in a device being created in the target portion, such as an integrated circuit.

The patterning device may be transmissive or reflective. Examples of patterning devices include masks, programmable mirror arrays, and programmable LCD panels. Masks are well known in lithography, and include mask types such as binary, alternating phase-shift, and attenuated phase-shift, as well as various hybrid mask types. An example of a programmable mirror array employs a matrix arrangement of small mirrors, each of which can be individually tilted so as to reflect an incoming radiation beam in different directions. The tilted mirrors impart a pattern in a radiation beam which is reflected by the mirror matrix.

The projection system, like the illumination system, may include various types of optical components, such as refractive, reflective, magnetic, electromagnetic, electrostatic or other types of optical components, or any combination thereof, as appropriate for the exposure radiation being used, or for other factors such as the use of a vacuum. It may be desired to use a vacuum for EUV radiation since other gases may absorb too much radiation. A vacuum environment may therefore be provided to the whole beam path with the aid of a vacuum wall and vacuum pumps.

As here depicted, the apparatus is of a reflective type (e.g., employing a reflective mask).

The lithographic apparatus may be of a type having two (dual stage) or more substrate tables (and/or two or more mask tables). In such “multiple stage” machines the additional tables may be used in parallel, or preparatory steps may be carried out on one or more tables while one or more other tables are being used for exposure.

Referring to FIG. 1, the illuminator IL receives an extreme ultraviolet (EUV) radiation beam from the source collector module SO. Methods to produce EUV radiation include, but are not necessarily limited to, converting a material into a plasma state that has at least one element, e.g., xenon, lithium or tin, with one or more emission lines in the EUV range. In one such method, often termed laser produced plasma (“LPP”) the required plasma can be produced by irradiating a fuel, such as a droplet of material having the required line-emitting element, with a laser beam. The source collector module SO may be part of an EUV radiation source including a laser, not shown in FIG. 1, for providing the laser beam exciting the fuel. The resulting plasma emits output radiation, e.g., EUV radiation, which is collected using a radiation collector, disposed in the source collector module.

The laser and the source collector module may be separate entities, for example when a CO₂ laser is used to provide the laser beam for fuel excitation. In such cases, the radiation beam is passed from the laser to the source collector module with the aid of a beam delivery system comprising, for example, suitable directing mirrors and/or a beam expander. The laser and a fuel supply may be considered to comprise an EUV radiation source.

The illuminator IL may comprise an adjuster for adjusting the angular intensity distribution of the radiation beam. Generally, at least the outer and/or inner radial extent (commonly referred to as σ-outer and σ-inner, respectively) of the intensity distribution in a pupil plane of the illuminator can be adjusted. In addition, the illuminator IL may comprise various other components, such as facetted field and pupil mirror devices. The illuminator may be used to condition the radiation beam, to have a desired uniformity and intensity distribution in its cross-section.

The radiation beam B is incident on the patterning device (e.g., mask) MA, which is held on the support structure (e.g., mask table) MT, and is patterned by the patterning device. After being reflected from the patterning device (e.g., mask) MA, the radiation beam B passes through the projection system PS, which focuses the beam onto a target portion C of the substrate W. With the aid of the second positioner PW and position sensing system PS2 (e.g., using interferometric devices, linear encoders or capacitive sensors), the substrate table WT can be moved accurately, e.g., so as to position different target portions C in the path of the radiation beam B. Similarly, the first positioner PM and another position sensing system PS1 can be used to accurately position the patterning device (e.g., mask) MA with respect to the path of the radiation beam B. Patterning device (e.g., mask) MA and substrate W may be aligned using mask alignment marks M1, M2 and substrate alignment marks P1, P2.

The depicted apparatus could be used in at least one of the following modes:

1. In step mode, the support structure (e.g., mask table) MT and the substrate table WT are kept essentially stationary, while an entire pattern imparted to the radiation beam is projected onto a target portion C at one time (i.e., a single static exposure). The substrate table WT is then shifted in the X and/or Y direction so that a different target portion C can be exposed.

2. In scan mode, the support structure (e.g., mask table) MT and the substrate table WT are scanned synchronously while a pattern imparted to the radiation beam is projected onto a target portion C (i.e., a single dynamic exposure). The velocity and direction of the substrate table WT relative to the support structure (e.g., mask table) MT may be determined by the (de-)magnification and image reversal characteristics of the projection system PS.

3. In another mode, the support structure (e.g., mask table) MT is kept essentially stationary holding a programmable patterning device, and the substrate table WT is moved or scanned while a pattern imparted to the radiation beam is projected onto a target portion C. In this mode, generally a pulsed radiation source is employed and the programmable patterning device is updated as required after each movement of the substrate table WT or in between successive radiation pulses during a scan. This mode of operation can be readily applied to maskless lithography that utilizes a programmable patterning device, such as a programmable mirror array of a type as referred to above.

Combinations and/or variations on the above described modes of use or entirely different modes of use may also be employed.

FIG. 2 shows the lithographic apparatus 100 in more detail, including the source collector module SO, the illumination system IL, and the projection system PS. The source collector module SO is constructed and arranged such that a vacuum environment can be maintained in an enclosing structure 220 of the source collector module.

A laser LA is arranged to deposit laser energy via a laser beam 205 into a fuel, such as xenon (Xe), tin (Sn) or lithium (Li) which is provided from a fuel supply 200. This creates a highly ionized plasma 210 at a plasma formation location 211 which has electron temperatures of several 10's of eV. The energetic radiation generated during de-excitation and recombination of these ions is emitted from the plasma, collected and focussed by a near normal incidence radiation collector CO. The laser LA and fuel supply 200 may together be considered to comprise an EUV radiation source. The EUV radiation source may be referred to as a laser produced plasma (LPP) source.

A second laser (not shown) may be provided, the second laser being configured to preheat the fuel before the laser beam 205 is incident upon it. An LPP source which uses this approach may be referred to as a dual laser pulsing (DLP) source.

Radiation that is reflected by the radiation collector CO is focused at a virtual source point IF. The virtual source point IF is commonly referred to as the intermediate focus, and the source collector module SO is arranged such that the intermediate focus IF is located at or near to an opening 221 in the enclosing structure 220. The virtual source point IF is an image of the radiation emitting plasma 210.

Subsequently the radiation traverses the illumination system IL, which may include a facetted field mirror device 22 and a facetted pupil mirror device 24 arranged to provide a desired angular distribution of the radiation beam 21 at the patterning device MA, as well as a desired uniformity of radiation intensity at the patterning device MA. Upon reflection of the beam of radiation 21 at the patterning device MA, held by the support structure MT, a patterned beam 26 is formed and the patterned beam 26 is imaged by the projection system PS via reflective elements 28, 30 onto a substrate W held by the wafer stage or substrate table WT.

The stream of fuel droplets comprises fuel droplets having a diameter of, for example, 19 microns, a velocity of, for example, 100 m/s and a separation of, for example, 1 mm. This exemplary velocity and separation corresponds with a frequency of 100 kHz. Therefore, in this particular example fuel droplets with a diameter of 19 microns are delivered to the plasma formation location with a frequency of 100 kHz. This may be desirable from the point of view of efficient generation of EUV radiation via conversion of the fuel droplets to the plasma by the laser beam 205 (see FIG. 2).

In this exemplary embodiment the fuel droplet size and the fuel droplet frequency are interlinked, and would both be linked to the diameter of the nozzle through which the droplets are discharged. The diameter of the nozzle may for example be 3 microns or more. The diameter of the nozzle may be chosen to provide fuel droplets having a desired diameter (and hence a desired volume of fuel material). It may be desirable to provide fuel droplets having a diameter of around 20 microns. Fuel droplets of this diameter are sufficiently large that the risk of the laser beam 205 missing the fuel droplets is very small, and are sufficiently small that most of the fuel is converted by the laser beam into plasma and contamination due to unvaporized fuel material is low. The nozzle may for example have a diameter of up to 10 microns.

The nozzle may for example have a diameter which gives rise via Rayleigh break-up to fuel droplets having a desired diameter. Alternatively, the nozzle may have a diameter which gives rise to smaller fuel droplets that subsequently coalesce together to form fuel droplets having a desired diameter.

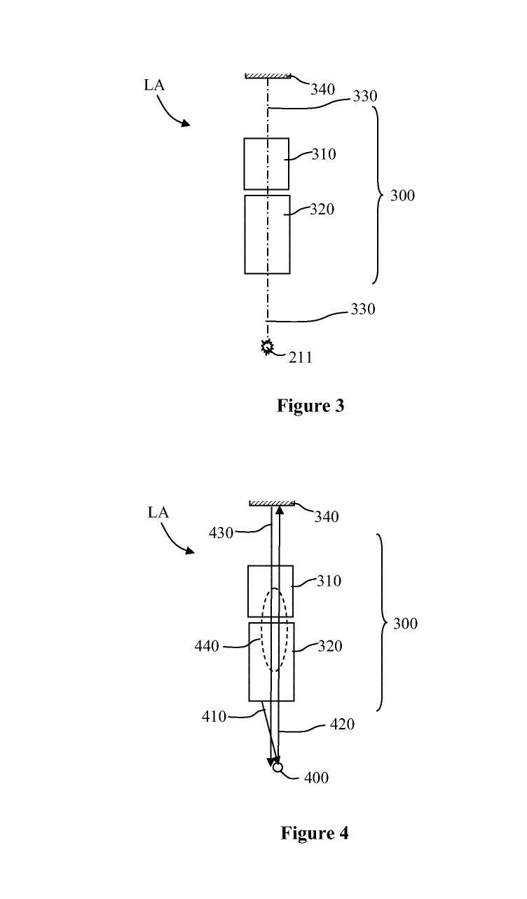

FIG. 3 schematically depicts a prior art laser which may be used as laser LA to generate the laser radiation 205 shown in FIG. 2. The prior art laser LA of FIG. 3 comprises an amplifier 300 having two amplifier chambers 310 and 320. The amplifier chambers 310, 320 may each comprise an optical gain medium positioned along a beam path 330. The laser LA further comprises a wavelength selective cavity mirror 340, e.g., a Littrov grating, constructed and arranged to reflect radiation incident on the cavity minor 340 from a position on the beam path 330 back in the opposite direction. The cavity mirror 340 may for example be a Littrov grating, a flat mirror, a curved minor, a phase-conjugate minor or a corner reflector.

With reference to FIG. 4, when a fuel droplet 400 reaches the plasma formation position, spontaneously emitted photons 410 from optical gain media in the amplifier chambers 310, 320 are scattered by the droplet 400. Some of these scattered photons 420 are directed back into the amplifier 300. These photons 420 are amplified by the amplifier 300, reflected 430 by the cavity mirror 340, and are then amplified again by the amplifier 300, thereby producing the laser radiation beam 205 which can then interact with the fuel droplet 400 to produce an EUV radiation-emitting plasma.

The laser beam 205 may have a wavelength between about 9 μm and about 11 μm. A wavelength of about 10.6 μm may be used, since radiation of that wavelength has proven to be particularly effective in producing an EUV radiation-emitting plasma. The optical gain media of the amplifier chambers 310, 320 may for example comprise a mixture of helium gas, nitrogen gas and CO2 gas, or any other suitable combination of gases.

A problem associated with the prior art laser depicted in FIGS. 3 and 4 is that the mode that builds-up is strongly dependent upon and confined around the initial trigger process, which results in the cavity only being used locally (see narrow oval section 440 in FIG. 4). This results in saturation of the gain medium, which limits the absolute power obtainable. Additionally, the moving droplet of fuel material flies by the initial trigger point, to which the laser fires back, with the result that the next reflection is less than optimal, which can lead to the development of an undesirable asymmetric mode.

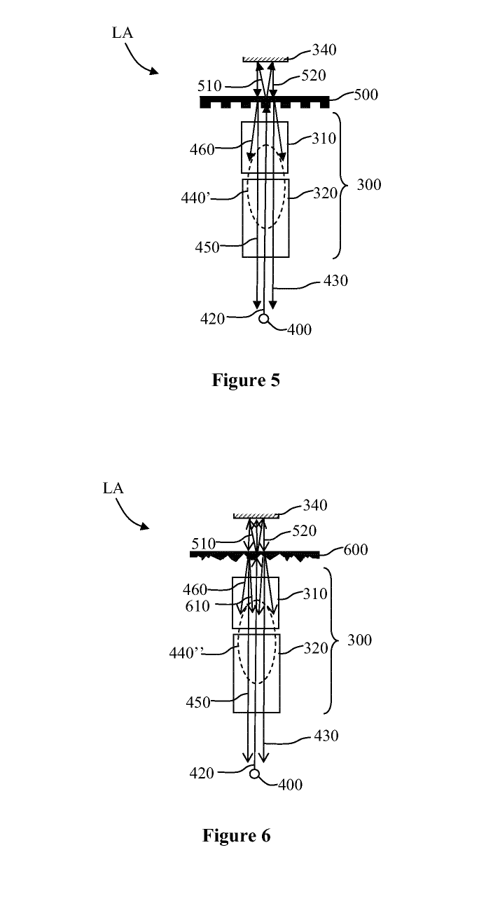

The aforementioned problems may be addressed by using a radiation source LA according to an embodiment of an aspect of the present invention. A first embodiment is depicted in FIG. 5 and a second embodiment is depicted in FIG. 6.

FIG. 5 shows a radiation source LA with a similar general arrangement to that of the prior art radiation source LA shown in FIGS. 3 and 4, but in which an optical element in the form of a phase grating 500 is provided in between the ‘gain’ amplifier chamber 310 and the cavity mirror 340. The phase grating 500 is configured so as to cause incident rays 420 from the fuel droplet 400 to diverge 510 from their otherwise linear path (not shown) towards the cavity mirror 340. The divergent rays 510 are then reflected by the cavity mirror 340 so as to follow a linear path 520 back towards the phase grating 500 whereupon they are further diverged from their otherwise linear path so as to follow a plurality of divergent paths 450, 460 through the amplifier 300. As a result of the phase grating 500 causing the rays to follow a divergent path through the amplifier, the laser beam is effectively widened so as to use a greater volume of the gain medium in one or more of the chambers 310, 320 of the amplifier 300 (depicted schematically as a widened oval 440′ in FIG. 5). In this way the laser LA according to the first embodiment of an aspect of the present invention depicted in FIG. 5 is less dependent upon the initial laser trigger impulse, provides a more stable beam of higher output power. Use of the phase grating also affords the opportunity to optimize the beam widening by controlling the grating pitch and its separation from the other components in the laser LA. While divergence of the beam may result in a certain level of power loss it is envisaged that this will be more than compensated for by the significantly increased power gain obtained by using a greater volume of the gain medium, at least in chamber 310 alone.

FIG. 6 shows a radiation source LA with a similar arrangement to that of the radiation source LA shown in FIG. 5, but in which the phase grating 500 has been replaced with an optical element in the form of a scatter plate 600. Scatter plate 600 is again provided in between the ‘gain’ amplifier chamber 310 and the cavity mirror 340. The scatter plate 600 is configured so as to cause incident rays 420 from the fuel droplet 400 to diverge 510 from their otherwise linear path (not shown) towards the cavity mirror 340 to a greater extent than the phase grating 500. Moreover, it is intended that the scatter plate 600 causes the reflected rays 520 traveling back towards the scatter plate 600 to be diverged from their otherwise linear path to a greater extent than the phase grating such that the rays follow a greater number of divergent paths 450, 460, 610 through the amplifier 300. As a result, the laser beam is again effectively widened so as to use a greater volume of the gain medium in one or more of the chambers 310, 320 of the amplifier 300 (depicted schematically as a widened oval 440″ in FIG. 6), which affords similar advantages to those set out above in relation to the embodiment shown in FIG. 5.

In the above described embodiments of the present invention the velocity of the fuel droplets is 100 m/s. The fuel droplets may be provided with any desired velocity. It may be desirable for the fuel droplets to have a high velocity. This is because the higher the velocity, the greater the separation distance between fuel droplets (for a given frequency of fuel droplet delivery at the plasma formation location). A greater separation is desirable because it reduces the risk that plasma generated by a preceding fuel droplet interacts with the next fuel droplet, for example causing a modification of the trajectory of that fuel droplet. A separation of 1 mm or more between droplets delivered to the plasma formation location may be desirable (although any separation may be used).

The timing of the droplet formation can be controlled by actuation of the nozzle by a piezo-electric actuator. The timing of droplet formation can therefore be adjusted by adjusting the phase of a drive signal supplied to the piezo-electric actuator. A controller may be configured to adjust the velocity of the fuel droplets and/or the timing of droplet formation.

The values of fuel droplet velocity, fuel droplet size, fuel droplet separation, fuel pressure in the reservoir, frequency of modulation applied by the piezo electric actuator, diameter of the nozzle and width of the openings are merely examples. Any other suitable values may be used.

In the above described embodiments of the present invention the fuel droplets are liquid tin. However, the fuel droplets may be formed from one or more other materials (e.g., in liquid form).

Radiation generated by the source may for example be EUV radiation. The EUV radiation may for example have a wavelength within the range of 5-20 nm, for example within the range of 13-14 nm, for example within the range of 5-10 nm such as 6.7 nm or 6.8 nm.

Although specific reference may be made in this text to the use of lithographic apparatus in the manufacture of ICs, it should be understood that the lithographic apparatus described herein may have other applications, such as the manufacture of integrated optical systems, guidance and detection patterns for magnetic domain memories, flat-panel displays, liquid-crystal displays (LCDs), thin-film magnetic heads, LED's, solar cells, photonic devices, etc. The skilled artisan will appreciate that, in the context of such alternative applications, any use of the terms “wafer” or “die” herein may be considered as synonymous with the more general terms “substrate” or “target portion”, respectively. The substrate referred to herein may be processed, before or after exposure, in for example a track (a tool that typically applies a layer of resist to a substrate and develops the exposed resist), a metrology tool and/or an inspection tool. Where applicable, the disclosure herein may be applied to such and other substrate processing tools. Further, the substrate may be processed more than once, for example in order to create a multi-layer IC, so that the term substrate used herein may also refer to a substrate that already contains multiple processed layers.

The term “lens”, where the context allows, may refer to any one or combination of various types of optical components, including refractive, reflective, magnetic, electromagnetic and electrostatic optical components.

While specific embodiments of the present invention have been described above, it will be appreciated that the present invention may be practiced otherwise than as described. The descriptions above are intended to be illustrative, not limiting. Thus it will be apparent to one skilled in the art that modifications may be made to the present invention as described without departing from the scope of the claims set out below.

It is to be appreciated that the Detailed Description section, and not the Summary and Abstract sections, is intended to be used to interpret the claims. The Summary and Abstract sections may set forth one or more but not all exemplary embodiments of the present invention as contemplated by the inventor(s), and thus, are not intended to limit the present invention and the appended claims in any way.

The present invention has been described above with the aid of functional building blocks illustrating the implementation of specified functions and relationships thereof. The boundaries of these functional building blocks have been arbitrarily defined herein for the convenience of the description. Alternate boundaries can be defined so long as the specified functions and relationships thereof are appropriately performed.

The foregoing description of the specific embodiments will so fully reveal the general nature of the present invention that others can, by applying knowledge within the skill of the art, readily modify and/or adapt for various applications such specific embodiments, without undue experimentation, without departing from the general concept of the present invention. Therefore, such adaptations and modifications are intended to be within the meaning and range of equivalents of the disclosed embodiments, based on the teaching and guidance presented herein. It is to be understood that the phraseology or terminology herein is for the purpose of description and not of limitation, such that the terminology or phraseology of the present specification is to be interpreted by the skilled artisan in light of the teachings and guidance.

The breadth and scope of the present invention should not be limited by any of the above-described exemplary embodiments, but should be defined only in accordance with the following claims and their equivalents.

1. A radiation source comprising:
a nozzle configured to direct a stream of fuel droplets along a trajectory towards a plasma formation location; and
a laser configured direct laser radiation, for instance radiation having a wavelength of between about 9 μm and about 11 μm, to the plasma formation location to convert the fuel droplets at the plasma formation location into a plasma,
wherein the laser comprises an amplifier and an optical element configured to define a divergent beam path for radiation passing through the amplifier.

2. The radiation source of claim 1, wherein the laser is configured to generate a pulse of laser radiation when photons emitted from the amplifier are reflected along the divergent beam path by a fuel droplet.

3. The radiation source of claim 2, wherein the laser comprises a cavity mirror arranged to reflect photons reflected by fuel droplets, and the optical element is provided in between the amplifier and the cavity mirror.

4. The radiation source of claim 1, wherein the amplifier comprises a plurality of amplifier chambers.

5. The radiation source of claim 4, wherein the optical element is provided in between the cavity mirror and the amplifier chamber closest to the cavity mirror.

6. The radiation source of claim 1, wherein the optical element comprises a phase grating.

7. The radiation source of claim 1, wherein the optical element comprises a scatter plate.

8. The radiation source of claim 1, wherein the radiation source further comprises a collector mirror configured to collect and focus radiation generated by the plasma formed from the fuel droplets.

9. The radiation source of claim 1, wherein the plasma produced by conversion of the fuel droplets is EUV radiation emitting plasma.

10. The radiation source of claim 1, wherein the nozzle is configured to emit fuel droplets as single droplets.

11. The radiation source of claim 1, wherein the nozzle is configured to emit fuel droplets as clouds of fuel which subsequently coalesce into droplets.

12. The radiation source of claim 1, wherein the fuel droplets comprise or consist of Xe, Li or Sn.

13. The radiation source of claim 1, wherein the laser is a CO2 laser.

14. A lithographic apparatus comprising
a radiation source configured to generate a radiation beam, the radiation source comprising:
a nozzle configured to direct a stream of fuel droplets along a trajectory towards a plasma formation location; and
a laser configured to direct laser radiation, for instance radiation having a wavelength of between about 9 μm and about 11 μm, to the plasma formation location to convert the fuel droplets at the plasma formation location into a plasma,
wherein the laser comprises an amplifier and an optical element configured to define a divergent beam path for radiation passing through the amplifier,
an illumination system configured to condition the radiation beam,
a support constructed to support a patterning device, the patterning device being capable of imparting the radiation beam with a pattern in its cross-section to form a patterned radiation beam,
a substrate table constructed to hold a substrate, and
a projection system configured to project the patterned radiation beam onto a target portion of the substrate.

15. A method comprising:
emitting a stream of fuel droplets from a nozzle along a trajectory towards a plasma formation location and using a laser to direct laser radiation to the plasma formation location to convert the fuel droplets at the plasma formation location into a plasma, wherein the laser comprises an amplifier and an optical element; and
using the optical element to define a divergent beam path for radiation passing through the amplifier.
